(19) United States
(12) Patent Application Publication
(10) Pub. No.: US 2025/0147134 A1
(43) Pub. Date: May 8, 2025

(54) MAGNETIC RESONANCE SIMULATION APPARATUS, MAGNETIC RESONANCE SIMULATION METHOD, AND MAGNETIC RESONANCE IMAGING APPARATUS

(71) Applicant: CANON MEDICAL SYSTEMS CORPORATION, Otawara-shi (JP)

(72) Inventor: Hidenori TAKESHIMA, Tokyo (JP)

(73) Assignee: CANON MEDICAL SYSTEMS CORPORATION, Otawara-shi (JP)

(21) Appl. No.: 18/928,556

(22) Filed: Oct. 28, 2024

(30) Foreign Application Priority Data
Nov. 7, 2023 (JP) 2023-190013

(51) Int. Cl. G01R 33/54; G01R 33/50; G01R 33/56

(52) U.S. Cl. CPC G01R 33/546; G01R 33/50; G01R 33/5608

(57) ABSTRACT

A magnetic resonance simulation apparatus according to an embodiment includes processing circuitry. The processing circuitry obtains phantom information and group information. The phantom information represents a phantom having an ensemble of positions and physical values relative to a plurality of isochromats. The group information represents groups of isochromats classified with respect to the phantom information, the isochromats that exhibit a same physical magnetization property under a condition preset according to a pulse sequence. Based on the group information and the phantom information, the processing circuitry collectively performs a magnetic resonance simulation with respect to isochromats classified as a same group among the plurality of isochromats, to output a simulation result obtained from the magnetic resonance simulation.

### CROSS-REFERENCE TO RELATED APPLICATIONS

This application is based upon and claims the benefit of priority from Japanese Patent Application No. 2023-190013, filed on Nov. 7, 2023; the entire contents of which are incorporated herein by reference.

### FIELD

Embodiments described herein relate generally to a magnetic resonance simulation apparatus, a magnetic resonance simulation method, and a magnetic resonance imaging apparatus.

### BACKGROUND

Conventionally, magnetic resonance simulations using the Bloch equations are required to achieve both precision and acceleration. For example, in a magnetic resonance simulation focusing on acceleration, a matrix (referred to as a combined transition matrix) is computed by combining transform matrices during an RF-pulse application period, prior to performing the magnetic resonance simulation. The transform matrices (transition matrices) describe state transformations (state transitions) of particles in response to RF pulses. Using isomagnetic lines, for example, isochromats are sorted according to Z-directional field values after application of a gradient field, to compute a state transition of particles once at each location with the same Z-directional field value. This sorting, however, takes a large amount of computation time since the isochromats need to be sorted for each pulse sequence waveform (RF and gradient field pattern).

Further, the sorting may result in no redundancy found in the Z-directional magnetic field. In such a case the sorting computations come to nothing. In particular, in a higher-precision magnetic resonance simulation such redundancy may not be found. In addition, even a slight change of the Z-directional magnetic field causes re-computation of the combined transition matrix in the magnetic resonance simulation. It is thus not possible to reuse a pre-computed combined transition matrix for different magnetic resonance simulations.

### BRIEF DESCRIPTION OF THE DRAWINGS

FIG. 1 is a schematic block diagram illustrating an exemplary magnetic resonance simulation apparatus according to a first embodiment;

FIG. 2 illustrates a pulse sequence by a spin echo method according to the first embodiment as an example;

FIG. 3 is a schematic diagram illustrating an outline of isochromat grouping according to the first embodiment as an example;

FIG. 4 illustrates an example of group information according to the first embodiment;

FIG. 5 is a flowchart illustrating steps of an MR simulation process according to the first embodiment by way of example;

FIG. 6 illustrates an obtained pulse sequence and gradient field types in portions of the pulse sequence according to the first embodiment, as an example;

FIG. 7 illustrates a selection of group information for a gradient field type during an RF application period in the pulse sequence of FIG. 6 according to the first embodiment, as an example;

FIG. 8 illustrates a selection of group information for a gradient field type during an MR-signal acquisition period in the pulse sequence of FIG. 6 according to the first embodiment, as an example;

FIG. 9 illustrates a process A in overview according to the first embodiment, as an example;

FIG. 10 illustrates a process B in overview according to the first embodiment, as an example;

FIG. 11 illustrates a process C in overview according to the first embodiment, as an example;

FIG. 12 illustrates an example of group information according to a first application of the first embodiment;

FIG. 13 illustrates an example of an M₀-map generation process with clustering in overview according to a third application of the first embodiment; and

FIG. 14 is a schematic block diagram illustrating a configuration of a magnetic resonance imaging apparatus according to a second embodiment, as an example.

### DETAILED DESCRIPTION

According to an embodiment, a magnetic resonance simulation apparatus includes processing circuitry. The processing circuitry obtains phantom information and group information. The phantom information represents a phantom having an ensemble of positions and physical values relative to a plurality of isochromats. The group information represents groups of isochromats classified with respect to the phantom information, the isochromats that exhibit a same physical magnetization property under a condition preset according to a pulse sequence. Based on the group information and the phantom information, the processing circuitry collectively performs a magnetic resonance simulation with respect to isochromats classified as a same group among the plurality of isochromats, to output a simulation result obtained from the magnetic resonance simulation.

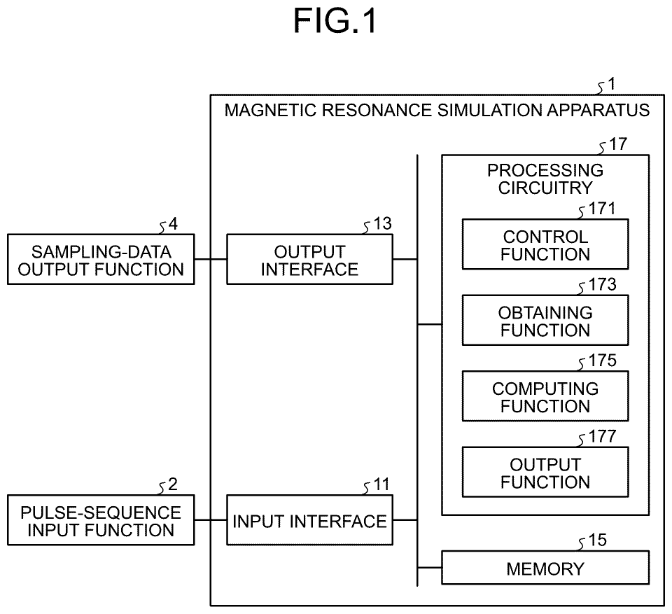

Hereinafter, exemplary embodiments of a magnetic resonance (MR) simulation apparatus, an MR simulation method, and a magnetic resonance imaging (MRI) apparatus will be described in detail with reference to the accompanying drawings. FIG. 1 is a schematic block diagram illustrating one example of an MR simulation apparatus 1.

### First Embodiment

In the following, for the sake of specificity the magnetic resonance simulation apparatus 1 is defined to compute or simulate a magnetic resonance phenomenon using the Bloch equations phenomenologically describing magnetic resonance in classical mechanics. The MR simulation apparatus 1 applies, for example, the Rodrigues' rotation formula to numerically compute magnetic resonance. In addition to the Rodrigues' rotation formula, the MR simulation apparatus 1 can apply other methods or approaches, such as the Runge-Kutta method and the Runge-Kutta method with adaptive time steps, for the numerical simulation of magnetic resonance. Examples of other magnetic-resonance phenomenon simulation methods include the Bloch-Torrey equations and the Bloch-McConnel equations, in addition to the Bloch equations.

In the MR simulation numerically computing a magnetic resonance phenomenon, a virtual molecule is set in the center of each of voxels of a phantom. Each voxel may correspond to an isochromat, for example. The phantom has an ensemble of positions and physical values relative to multiple isochromats. The physical values include, for example, a longitudinal relaxation time (T₁), a transverse relaxation time (T₂), and a non-uniform external magnetic field (ΔB₀). The non-uniform external magnetic field may include a non-uniform static magnetic field and a chemical shift. A memory 15 stores therein phantom information representing the phantom including an ensemble of positions and physical values relative to the multiple isochromats.

Time evolution of the magnetizations of isochromats (chronological magnetization state transition) is given by the Bloch equations. The chronological state transition can be preset by a pulse sequence at each time point in the MR simulation. The pulse sequence refers to information (sequence information) including definitions of imaging procedures, for example.

The pulse sequence contains, for example, definitions as to intensity and timing of current supplied from the gradient field supply to the gradient field coils in the magnetic resonance imaging (MRI) apparatus, intensity and application timing of RF pulse supplied from the transmitter circuitry to the transmission coil in the MRI apparatus, and MR-signal detection timing by the receiver circuitry in the MRI apparatus.

The MR simulation apparatus 1 includes, for example, an input interface 11, an output interface 13, the memory 15, and processing circuitry 17. The MR simulation apparatus 1 may additionally include an external storage or storages (e.g., various kinds of storage or memory) that store computer programs for causing the processing circuitry 17 to implement various functions and/or resultant outputs from an output function 177.

The external storage or storages may be, for example, a driver that reads and writes various kinds of information from and to a semiconductor memory device such as a hard disk drive (HDD), a solid state drive (SSD), random access memory (RAM), or flash memory, an optical disk such as a compact disc (CD) and a digital versatile disk (DVD), or a portable storage medium, for example.

The input interface 11 is, for example, electrically connected to a pulse-sequence input function 2 of the MRI apparatus. Specifically, the input interface 11 is connected to the output terminal of the pulse-sequence input function 2 in the MRI apparatus.

In place of being connected to the MRI apparatus, the input interface 11 may be, for example, connected to an external device (e.g., sequence generator) capable of generating pulse sequence data as to MR imaging for output. Further, the connection between the input interface 11 and various kinds of devices as a source of pulse sequences may be established via a network.

The input interface 11 may further include an input device that receives various kinds of instructions and information inputs from the user. Such an input interface 11 corresponds to, for example, a pointing device such as a mouse and a trackball or an input device such as a keyboard. As an example, according to a user instruction, the input interface 11 receives a pulse sequence to be a subject of MR simulation.

The input interface 11 may allow the user to input an output instruction as to a result of an MR simulation by the MR simulation apparatus 1. The output instruction refers to an instruction for the output interface 13 to output results of an MR simulation to various kinds of external devices and/or displays, for example. The input interface 11 corresponds to an input unit.

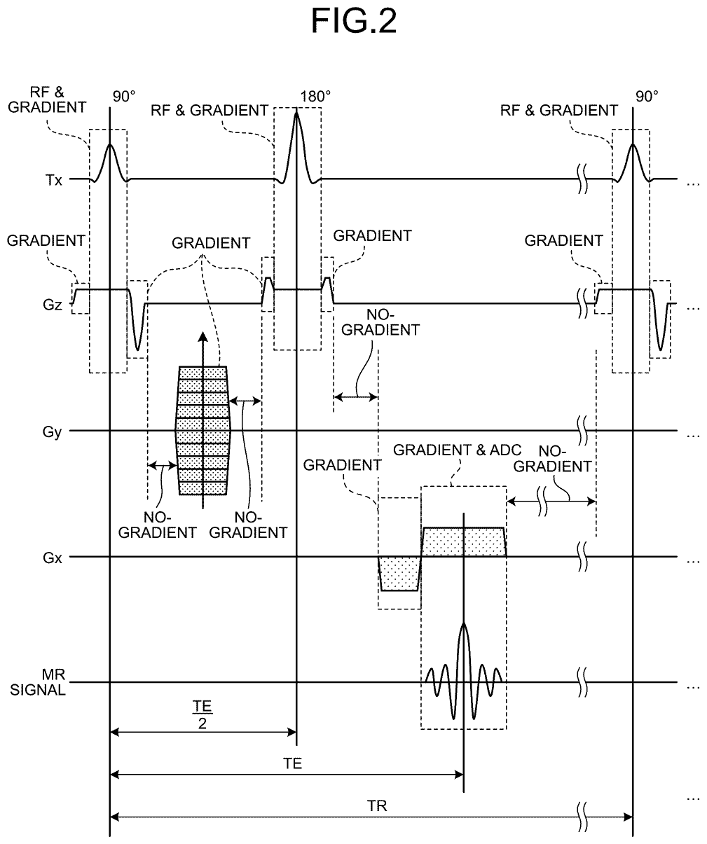

FIG. 2 illustrates a pulse sequence according to a spin echo method as an example. In FIG. 2, Tx represents a magnitude of transmission RF pulses. Gz represents a slice-selective gradient field. Gy represents a phase-encoding gradient field. Gx represents a readout gradient field. In the pulse sequence of FIG. 2, a readout gradient field is applied to acquire MR signals after an echo time (TE) passes from the application of a 90-degree RF pulse.

MR signals are converted into digital signals by an analog-to-digital converter (ADC). Although not shown in FIG. 2, any of various kinds of pulses such as preparation pulse may be suitably applied depending on a pulse sequence type.

As illustrated in FIG. 2, the pulse sequence is represented by a combination of application of a gradient field (Gradient), application of an RF pulse and a gradient field (RF & Gradient), application of a gradient field and A/D conversion (Gradient & ADC), and a duration of no application of a gradient field (No-Gradient). In the spin echo method of FIG. 2, for example, the combination of Gradient, RF & Gradient including an RF pulse application, Gradient & ADC to acquire MR signals, and No-Gradient is iterated a number of times corresponding to the number of phase encoding steps. In each phase encoding, Gradient and No-Gradient are calculated (calculation of relaxation) once and Gradient & ADC is iteratively calculated a number of times equal to the number of ADCs (number of samplings) in FIG. 2. The number of the Gradient and No-Gradient calculations is less than that of the RF & Gradient calculations, for example.

The pulse-sequence input function 2 inputs, to the input interface 11, Gradient such as prepulse, RF & Gradient, Gradient such as crusher, RF & Gradient, Gradient & ADC, and No-Gradient in a time series. The input interface 11 outputs Gradient, RF & Gradient, RF & Gradient, Gradient & ADC, and No-Gradient to the processing circuitry 17 in a time series.

The pulse sequence of the present embodiment is not limited to the pulse sequence illustrated in FIG. 2. In a typical pulse sequence, a combination of RF & Gradient, Gradient, Gradient & ADC, and No-Gradient is iterated appropriately. The input interface 11 may also be connected to, for example, the output terminal of the transmitter circuitry and the output terminal of the gradient power supply in the MRI apparatus. In this case the input interface 11 receives a voltage signal and a current signal corresponding to a gradient field strength, an application timing of the gradient field, an application timing of a current and an RF pulse to be supplied to the transmission coil, and an MR-signal detection timing from the MRI apparatus.

The output interface 13 is, for example, connected to a sampling-data output function 4 of sequence control circuitry in the MRI apparatus. The output interface 13 outputs signal values computed by the output function 177 to the sampling-data output function 4, under the control of a control function 171. In addition to the sequence control circuitry, the output interface 13 may be connected to various kinds of devices (e.g., various kinds of displays, analyzers, and image generators) that use such output values for display, analysis, or processing.

The output interface 13 and various kinds of devices being destinations of the output values may be connected together via a network. Further, the output interface 13 may include a display that displays output values and else under the control of the control function 171. Examples of the display include a known display device such as a liquid crystal display.

The memory 15 may be, for example, a storage that stores therein various kinds of information, such as a hard disk drive (HDD), a solid state drive (SSD), or a semiconductor circuit memory device. In addition to the HDD or SSD, the memory 15 may be a driver that reads and writes various kinds of information from and to a portable storage medium such as a compact disc (CD), a digital versatile disk (DVD), or a flash memory, or a semiconductor memory device such as random access memory (RAM), for example.

The memory 15 stores, for example, a variety of computer programs for execution of the control function 171, an obtaining function 173, a computing function 175, and an output function 177. The memory 15 also stores, for example, various kinds of data generated by the execution of the control function 171, the obtaining function 173, the computing function 175, and the output function 177. The memory 15 corresponds to a storage unit.

For example, the memory 15 stores pulse sequences input via the input interface 11. The memory 15 further stores look-up tables generated at the time of phantom designing or phantom setting to the MR simulation apparatus 1. The look-up tables may be generated during the initial pulse-sequence waveform processing. The look-up table may be generated by, for example, dividing a pulse sequence into four gradient field types and classifying multiple isochromats according to the four gradient field types. The look-up table contains group information based on the classification of the multiple isochromats. Among the isochromats of the phantom, there are isochromats having the same T₁ (longitudinal relaxation time, T₂ (transverse relaxation time), and ΔB₀ (non-uniform external magnetic field) (hereinafter, referred to as same-physical-value isochromats). The group information represents a group of isochromats having a gradient field applied at the same intensity among the same-physical-value isochromats. Of the same-physical-value isochromats, the isochromats having a gradient field applied at the same intensity have the same physical properties of magnetization (hereinafter, physical properties) (hereinafter, referred to as same-property isochromats).

Specifically, the group information represents a classification of isochromats which exhibit the same physical properties under a condition preset according to a pulse sequence (hereinafter, a predetermined condition). The predetermined condition includes non-application of a gradient field in at least one direction in a pulse sequence. In more detail, the group information is based on the physical values and the gradient-field applied positions in the isochromats. In the following, the predetermined condition is defined to include non-application of a gradient field in two mutually orthogonal directions for the sake of specificity. One group corresponds to an ensemble of isochromats exhibiting the same magnetization state transition among the multiple isochromats. The look-up tables are stored in the memory 15 in association with the phantom information as to phantoms based on which the look-up tables are generated.

Specifically, the multiple isochromats are classified into groups of same-property isochromats by gradient-field directions (Gx, Gy, Gz) in an RF-pulse application period (RF & Gradient) and in an MR-signal acquisition period (Gradient & ADC) of a pulse sequence. Such grouping is performed on a phantom basis. The periods of interest in this disclosure are not limited to the two periods above. It may be possible to group the isochromats in, for example, Gradient and No-Gradient periods and perform the process same as in the RF & Gradient period (where RF is defined to be constantly zero).

As an example, in the grouping, first, at least one of Gx, Gy, and Gz at the respective positions (x, y, z) of the multiple isochromats in one phantom is set to zero and a coordinate of at least one of the positions (x, y, z) is set to zero accordingly. This creates seven different combinations of physical properties (positions and physical values) for one isochromat, for instance. Next, the look-up table generation process is performed in such a manner that among the multiple isochromats, isochromats having the same seven combinations are classified into a same group and isochromats not having the same seven combinations are not classified into a same group. Thereby, a look-up table with entries corresponding to the combinations of isochromats and gradient fields of zero is generated. This process can be accelerated by defining a hash function that allows collision mitigation and classifying the isochromats according to a hash key or a hash value, for example. Alternatively, collision determination can be made by defining a comparison function adapted for the combinations and sorting the isochromats using the comparison function. Note that JP H9-47442A discloses such sorting by the comparison function that directly uses the Z-directional magnetic field strength of each isochromat. However, the sorting in this disclosure distinctively differs from such a known method in that the isochromats are sorted according to the physical properties independent of the gradient field strength (i.e., the gradient field strength is optionally changeable) in the Z-directional gradient field of non-zero. The direct use of the Z-directional magnetic field strength in the comparison function as described in JP H9-47442A is unfavorable since every time the gradient field strength varies, the sorting process needs to be performed all over again.

For example, in the case of no application of a gradient field (No-Gradient), a look-up table #1 (entry No. 1) corresponding to No-Gradient is used. In this case, isochromat positions are arbitrary and isochromats having the same physical values (T₁, T₂, ΔB₀) are grouped as the same-property isochromats. The same-property isochromats are given first indexes (indexes in the look-up table) depending on differences in physical values. In this manner the first indexes and the same-property isochromats are registered in the look-up table #1 in association with each other. Then, a collision process is conducted to search the look-up table for the same isochromats already registered. To accelerate this collision process, the hashing method can be used for the generation of the look-up tables. Different first indexes are assigned to isochromats having different physical values. As such, in the case of non-application of a gradient field (No-Gradient), the multiple isochromats can be sorted into groups with the same magnetization state transitions.

When only a gradient field Gx is applied, a look-up table #2 is used. Of the isochromats at the same position x, the same-property isochromats are given second indexes (indexes in the look-up table) depending on differences in physical values. The second indexes and the same-property isochromats are registered in the look-up table #2 in association with each other after the collision process. In other words, different second indexes are assigned to isochromats having different physical values at different x-coordinates. As such, in the case of application of only a gradient field Gx, the multiple isochromats can be sorted into groups with the same magnetization state transitions.

When only a gradient field Gy is applied, a look-up table #3 is used. Of the isochromats at the same position y, the same-property isochromats are given third indexes (indexes in the look-up table) depending on differences in physical values. The third indexes and the same-property isochromats are registered in the look-up table #3 in association with each other after the collision process. In other words, different third indexes are assigned to isochromats having different physical values at different y-coordinates. As such, in the case of application of only a gradient field Gy, the multiple isochromats can be sorted into groups with the same magnetization state transitions.

Further, when only a gradient field Gz is applied, a look-up table #4 is used. Of the isochromats at the same position z, the same-property isochromats are given fourth indexes (indexes in the look-up table) depending on differences in physical values. The fourth indexes and the same-property isochromats are registered in the look-up table #4 in association with each other after the collision process. In other words, different fourth indexes are assigned to isochromats having different physical values at different z-coordinates. As such, in the case of application of only a gradient field Gz, the multiple isochromats can be sorted into groups with the same magnetization state transitions.

The grouping, i.e., the generation of the look-up tables is performed for each of the phantoms by, for example, the control function 171 before execution of an MR simulation (e.g., in phantom setting or in the initial pulse-sequence waveform processing). Alternatively, a grouping function (not shown) rather than the control function 171 may perform the grouping. The grouping process is presented for illustrative purpose only and not limited to grouping of given data. Instead, phantoms as pre-arrayed datasets may be used for grouping, for example. Further, with regard to phantoms not involving with this disclosure, it is likely difficult to classify the isochromats into a small number of groups in the first place. In such a case, known clustering algorithms (e.g., K-Means method or Mean Shift method) may be suitably adopted using such phantoms as inputs to generate cluster groups as the same-property isochromat groups and use them in a look-up table. In this manner, the group information serving as look-up tables to be referred to for finding to which ordinal number of group an isochromat of an arbitrary number belongs, for example, is stored in the memory 15.

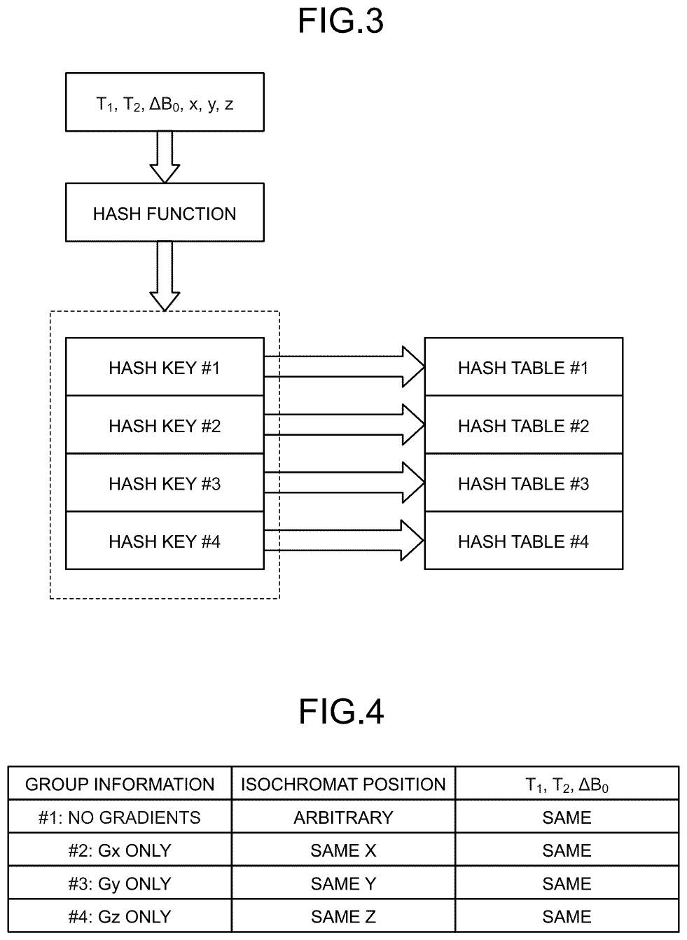

FIG. 3 illustrates an outline of isochromat grouping (classification) using a hash function as an example. As illustrated in FIG. 3, the respective positions and physical values of the multiple isochromats are inputted to the hash function along with zero positions according to gradient fields related to redundant magnetic field strengths. As a result, the hash function outputs hash keys #1 to #4. The hash keys #1 to #4 are associated with the first to fourth indexes. This forms hash tables #1 to #4, respectively. The positions and physical values of the isochromats associated with the hash keys are recorded separately to solve a collision which was unavoidable even with the hash keys (i.e., a collision resulting from different positions and physical values regarded as the same position and value by the same hash key), using the separately recorded positions and physical values. Thereby, the multiple isochromats are individually associated with the groups to which they belong using the indexes. Namely, the indexes correspond to identification numbers of the groups in a single hash key. Note that the above-described hash tables correspond to the look-up tables for the same-property isochromats, so that they are defined as look-up tables for the same-property isochromats for the purpose of avoiding limiting the hash tables to the hash process.

FIG. 4 illustrates a criterion for the group information by way of example. As illustrated in FIG. 4, the group information is based on the physical values (T₁, T₂, ΔB₀) and gradient-field applied positions (isochromat positions). Under a predetermined condition defining no application of gradient field (No Gradient), for example, the first indexes are assigned to the same-property isochromats having the same physical values, irrespective of the isochromat positions, referring to the same-property look-up table #1. Under a predetermined condition defining application of a gradient field Gx only, for example, the second indexes are assigned to the same-property isochromats having the same physical values at the same position x, referring to the same-property look-up table #2. Further, under a predetermined condition defining application of a gradient field Gy only, for example, the third indexes are assigned to the same-property isochromats having the same physical values at the same position y, referring to the same-property look-up table #3. Under a predetermined condition defining application of a gradient field Gz only, for example, the fourth indexes are assigned to the same-property isochromats having the same physical values at the same position z, referring to the same-property look-up table #4. The look-up table shown in FIG. 4 is generated for each of the phantoms and stored in the memory 15.

The processing circuitry 17 controls the operation of the MR simulation apparatus 1 as a whole in accordance with electric signals of inputs outputted from the input interface 11. For example, the processing circuitry 17 includes hardware resources such as a processor as a central processing unit (CPU), a micro processing unit (MPU), or a graphics processing unit (GPU), and memory such as read only memory (ROM) and RAM.

Alternatively, the processing circuitry 17 can be implemented by an application specific integrated circuit (ASIC), a field programmable gate array (FPGA), another complex programmable logic device (CPLD), or a simple programmable logic device (SPLD).

The processing circuitry 17 includes, for example, the control function 171, the obtaining function 173, the computing function 175, and the output function 177. The control function 171, the obtaining function 173, the computing function 175, and the output function 177 are individually stored in computer-executable program format in the memory 15. By using the processor that loads and executes the computer programs on the memory, the processing circuitry 17 performs the control function 171, the obtaining function 173, the computing function 175, and the output function 177.

Thus, the processing circuitry 17 corresponds to a processor that implements the functions corresponding to the programs by retrieving and executing the programs from the memory 15. In other words, having retrieved the respective programs, the processing circuitry 17 includes the functions corresponding to the programs. The control function 171, the obtaining function 173, the computing function 175, and the output function 177 may not be implemented by a single piece of processing circuitry. The processing circuitry can be constituted of a combination of multiple independent processors, so that the processors can individually execute the programs to implement the control function 171, the obtaining function 173, the computing function 175, and the output function 177. The processing circuitry 17 implementing the control function 171, the obtaining function 173, the computing function 175, and the output function 177 is one example of a control unit, an obtainer unit, a computation unit, and an output unit.

The processing circuitry 17 uses the control function 171 to control the respective functions of the processing circuitry 17. Specifically, the processing circuitry 17 retrieves and loads a control program from the memory 15 onto the internal memory, to control the respective elements of the MR simulation apparatus 1 according to the control program. The obtaining function 173, the computing function 175, and the output function 177 implemented by the processing circuitry 17 will be described later along the processing steps of an MR simulation (hereinafter, an MR simulation process).

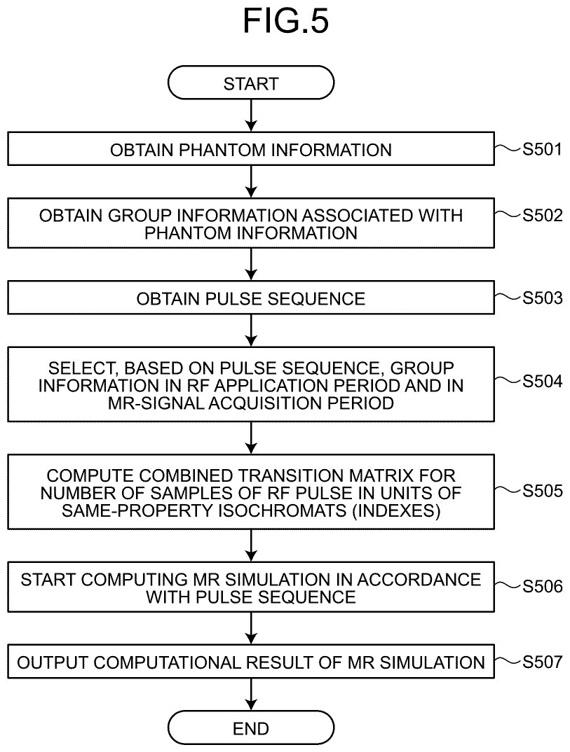

The overall configuration and structure of the MR simulation apparatus 1 have been described. Hereinafter, an MR simulation procedure will be explained. FIG. 5 is a flowchart illustrating one example of steps of an MR simulation process.

### MR Simulation Process

### Step S501

The processing circuitry 17 uses the obtaining function 173 to obtain phantom information for use in the MR simulation process. Specifically, the obtaining function 173 obtains the phantom information from the memory 15. Alternatively, the phantom information may be obtained from an external apparatus such as a sequence generator via the input interface 11, in addition to being obtained from the memory 15.

### Step S502

The processing circuitry 17 uses the obtaining function 173 to obtain group information relative to the phantom information. Specifically, the obtaining function 173 obtains, from the memory 15, the group information associated with the phantom information for use in the MR simulation process. Alternatively, the group information may be obtained from an external apparatus such as a sequence generator via the input interface 11 if the phantom information is obtained from the external apparatus, in addition to being obtained from the memory 15.

### Step S503

The processing circuitry 17 uses the obtaining function 173 to obtain a pulse sequence for MR imaging. Alternatively, the pulse sequence may be generated in response to a user instruction given via the input interface 11. The obtaining function 173 stores the pulse sequence in the memory 15. The pulse sequence may be obtained at any timing such as before the operation at step S501 or the operation at step S502.

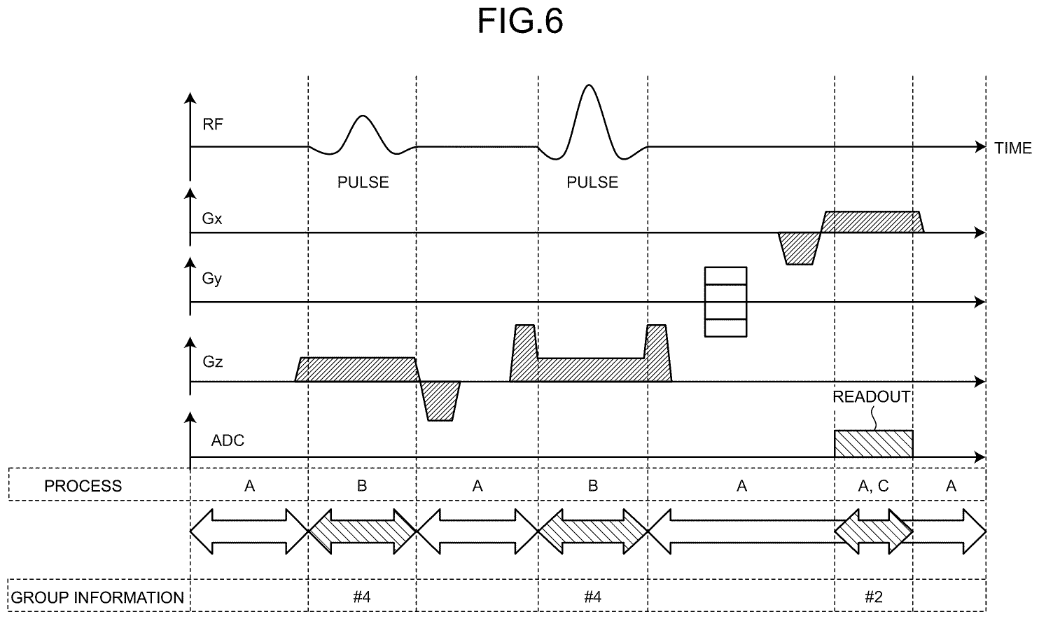

FIG. 6 illustrates an example of the obtained pulse sequence and gradient field types of portions of the pulse sequence. The characters “A”, “B”, and “C” in FIG. 6 indicate processes performed. FIG. 6 also shows the group information applied to the MR simulation in the RF application period and the acquisition period. As illustrated in FIG. 6, the pulse sequence to be processed is divided into three parts, RF pulses (RF), ADC sampling (ADC), and a remaining part. In the present embodiment, the RF part, ADC part, and remaining part are classified depending on gradient fields.

### Step S504

The processing circuitry 17 uses the computing function 175 to select, based on the pulse sequence, the group information in the RF application period. The computing function 175 further selects, based on the pulse sequence, the group information in the acquisition period. Thus, the computing function 175 classifies the multiple isochromats into two or more groups with respect to the RF-pulse application period (RF application period) of the pulse sequence, on the basis of the group information. Indexes are applied to the groups as group identifiers. The following will describe an example of determining group information for the pulse sequence of FIG. 6. Note that another known acceleration method may be applied to the part (remaining part) of the pulse sequence not covered by the group information.

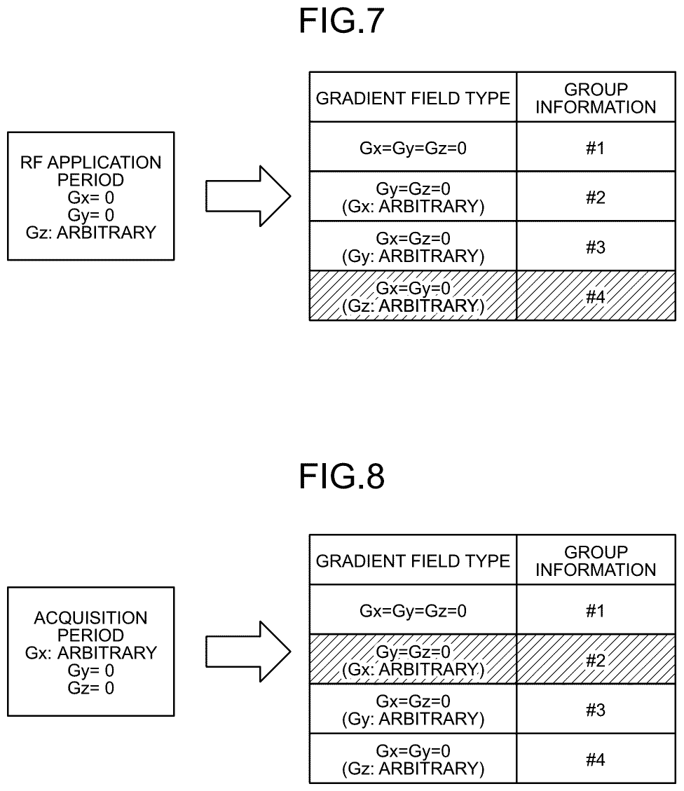

FIG. 7 illustrates a selection of the group information relative to a gradient field type in the RF application period of the pulse sequence in FIG. 6, as an example. As illustrated in FIG. 6, the Z-directional gradient field Gz and the RF pulse are applied during the RF application period. The computing function 175 thus determines group information #4 for the RF application period, as illustrated in FIG. 7.

FIG. 8 illustrates a selection of the group information relative to a gradient field type in the acquisition period of the pulse sequence in FIG. 6, as an example. As illustrated in FIG. 6, the X-directional gradient field Gx is applied during the acquisition period. The computing function 175 thus determines group information #2 for the acquisition period, as illustrated in FIG. 8.

### Step S505

The processing circuitry 17 uses the computing function 175 to integrate, in the RF application period, matrices describing magnetization state transitions (transition matrices) by the number of samples of the RF pulse with respect to each of the indexes included in the selected group information (#4 in FIG. 6), i.e., the same-property isochromats, to obtain a product of the matrices by integration (hereinafter, referred to as a combined transition matrix). That is, for each of the two or more groups, the computing function 175 computes the combined transition matrix describing magnetization state transitions of the isochromats for the number of the samples of the RF pulse.

In this manner, the computing function 175 computes the combined transition matrix for each of the indexes (elements) included in the group information #3. The resultant combined transition matrices correspond to matrices that allow a transition of a magnetization state of isochromats (same-property isochromats) located at the position with the same field strength during the RF application period. The computing function 175 stores, in the memory 15, the combined transition matrices for the corresponding elements contained in the selected group information.

### Step S506

The processing circuitry 17 uses the computing function 175 to start computing the MR simulation in accordance with the pulse sequence. Specifically, in a duration prior to the RF application, the computing function 175 computes time evolution of magnetizations of the multiple isochromats according to the process A. The following will describe details of the process A for computations related to Gradient and No-Gradient.

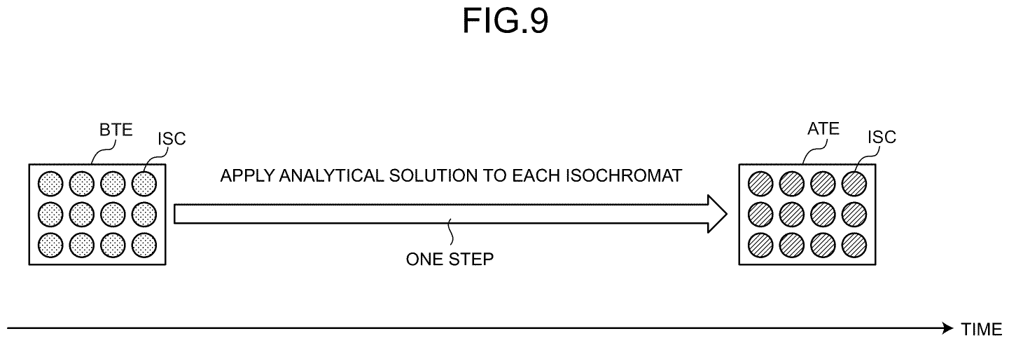

FIG. 9 illustrates an outline of the process A as an example. In FIG. 9, the circular marks inside the left-side box represent individual isochromats ISC prior to time evolution BTE while the circular marks inside the right-side box represent the individual isochromats ISC after time evolution ATE. Magnetization of each of the isochromats ISC can be computed by a single step, i.e., without iterated computations, by applying the physical values and positions of the individual isochromats ISC to the analysis solution of the Broch Equations. The resultant magnetizations of the isochromats ISC are stored in the memory 15.

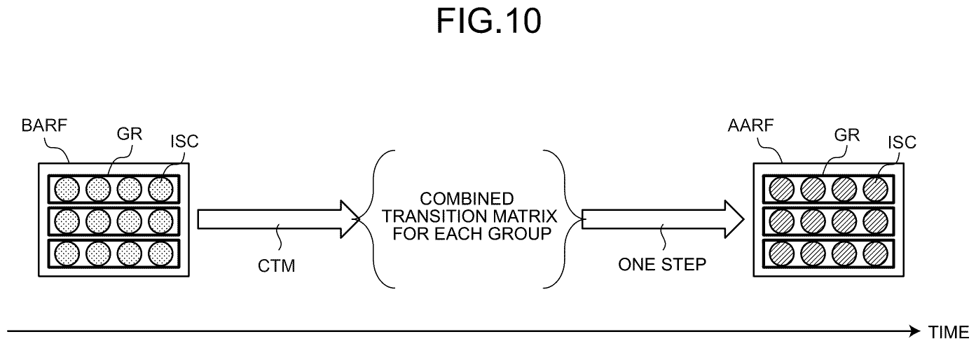

Next, in the RF application period, the processing circuitry 17 uses the computing function 175 to compute a magnetization state transition (time evolution) of the multiple isochromats by individually applying the combined transition matrices to the corresponding isochromat groups according to the process B. FIG. 10 illustrates an outline of the process B as an example. The following will describe details of the process B for computations related to RF & Gradient.

In FIG. 10, the circular marks inside the left-side box represent individual isochromats ISC immediately prior to an RF-pulse application BARF. The rectangles enclosing the four isochromats represent isochromat groups, i.e., the same-property isochromats. In FIG. 10 the arrow CTM indicates a computation of a combined transition matrix on a group basis (for each group identified as unique in the look-up table). In FIG. 10 the circular marks inside the right-side box represent the individual isochromats ISC after an RF application period AARF. Each combined transition matrix is computed in step S505 by integrating transition matrices for each group (in units of entries of the look-up table) for the number of RF-pulse applications. The combined transition matrices may be computed before the process B is performed at step S506, as illustrated in FIG. 10.

The combined transition matrix is computed in units of groups (entries of the look-up table) which have been identified based on the physical values and the positions of the isochromats ISC with reference to the look-up table. At step S506, by applying the combined transition matrix to the magnetization of each group immediately before the RF application period, the magnetization of each isochromat ISC is computed by a single step, i.e., without iterated computations for the individual isochromats ISC, as illustrated in FIG. 10. As such, based on the group information and the phantom information, the computing function 175 can collectively perform a magnetic resonance simulation with respect to the same group of isochromats among the multiple isochromats. The computing function 175 stores the magnetizations computed for the respective isochromats ISC in the memory 15.

As illustrated in FIG. 6, the processing circuitry 17 further uses the computing function 175 to successively perform the process A and the process B. The computing function 175 then performs the process A again. In addition, the computing function 175 computes MR-signal samplings by the process C in the acquisition period (Readout), using the magnetizations of the multiple isochromats immediately before the MR-signal samplings. In this manner, the computing function 175 performs A/D conversion (ADC) of the MR signals during the acquisition period (Readout).

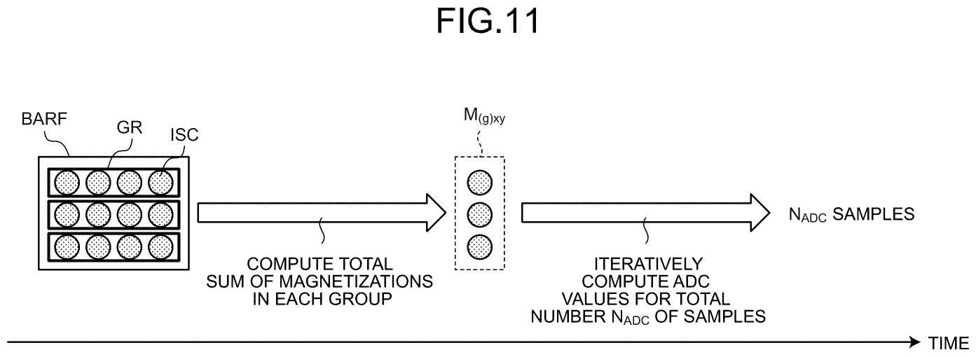

FIG. 11 illustrates an outline of the process C by way of example. The following will describe the process C for computations related to Gradient & ADC. Prior to the acquisition of the MR signals, the processing circuitry 17 uses the computing function 175 to compute a total sum of the magnetizations (transverse magnetizations M_{xy} and longitudinal magnetizations M_{z}) of the isochromats in each of the groups contained in the group information #2. Namely, the computing function 175 computes the total sum of the magnetizations of the isochromats in each of the groups for the MR-signal acquisition period of the pulse sequence. As such, the computing function 175 computes the total sum M_{(g)xy} (hereinafter, referred to as group magnetization) of the magnetizations (specifically, transverse magnetizations) of the groups for the same-property isochromats (group GR), as illustrated in FIG. 11.

Next, the processing circuitry 17 uses the computing function 175 to compute the transverse magnetizations of each of groups g relative to the group magnetization M_{(g)xy}(t) in a time interval from a starting point t₀ to a sampling point t of the acquisition period by the following Expression (1) using group-basis physical values. The computation of the transverse magnetizations relative to the group magnetization M_{(g)xy}(t) corresponds to the process A.

$${M}_{( g ) xy} ( t ) = {M}_{( g ) xy} ( {t}_{0} ) exp ( - \frac{t - {t}_{0}}{{T}_{2}} ) exp ( {\int }_{{t}_{0}}^{t} - i γ {B}_{z} ( t ) dt ) \qquad ( 1 )$$

By Expression (1), the computing function 175 computes the group magnetization M_{(g)xy}(t) at an arbitrary sampling point t. In Expression (1), B_{z} on the right side is represented by Gₓ(t)×x+G_{y}(t)×y+G_{z}(t)×z+ΔB for each of the same-property isochromats (B_{z}=Gₓ(t)×x+G_{y}(t)×y+G_{z}(t)×z+ΔB₀). Further, even the isochromats in motion can be grouped as long as the condition that the isochromats are at the same position at each time in a time series is satisfied. In such a case, Expression (1) is applicable by using higher-order moments of Bz (as in Expression (6) disclosed in [arXiv:2009.02789], “A Beginner's Guide to Bloch Equation Simulations of Magnetic Resonance Imaging Sequences”). The computing function 175 then computes an ADC value (ADCs(t)) at the arbitrary sampling point t by summing up the group magnetizations M_{(g)xy}(t) for the number of groups g as in Expression (2) below:

$$ADCs ( t ) = {\sum }_{g} {M}_{( g ) xy} ( t ) \qquad ( 2 )$$

When the total sampling number of the MR signal is N_{ADC} as illustrated in FIG. 11, the ADC value at the n-^{th} (1≤n≤N_{ADC}) MR-signal sampling can be obtained by substituting an elapsed time from the time to for the n-th sampling time t in Expression (1) and Expression (2).

Alternatively, the ADC value (ADCs(t)) can be obtained by another expression, in addition to by Expression (2). For example, the ADC value (ADCs(t)) may be computed by the following Expression (3), using reception coil sensitivity S according to the reception coil, the groups, and a sampling time:

$$ADCs ( t ) = {\sum }_{p} {\sum }_{g} S ( g , p , t ) {M}_{( g ) xy} ( t ) \qquad ( 3 )$$

where g is a suffix for identifying the groups, p is a suffix for identifying reception coils, and the sensitivity S (g, p, t) of the reception coil depends on the reception coil p, the group g, and the sampling time t.

As described above, the computing function 175 computes the total sum of magnetizations of the multiple isochromats on a group basis for the MR-signal acquisition period in the pulse sequence. The computing function 175 then computes relaxations of the resultant total sum based on the physical values at MR-signal sampling intervals and on a group basis. By summing the relaxations of the groups, the computing function 175 computes MR signals (ADC values (ADCs(t)) to be acquired at sampling intervals. The computing function 175 stores the resultant ADC values (ADCs(t)) in the memory 15. The process of step S506 is iterated a number of times corresponding to the total number of phase encodings.

### Step S507

Upon completion of the MR simulation for the pulse sequence, the processing circuitry 17 uses the output function 177 to output a simulation result (computational result) obtained by the MR simulation. For example, the output function 177 outputs the ADC values to external apparatuses, such as an MRI apparatus and an analyzer, and/or the display.

The MR simulation apparatus 1 according to the first embodiment described above obtains phantom information and group information. The phantom information represents a phantom having an ensemble of positions and physical values relative to the multiple isochromats, and the group information represents groups of isochromats classified with respect to the phantom information, the isochromats that exhibit the same physical magnetization property under the condition preset according to the pulse sequence. Based on the group information and the phantom information, the MR simulation apparatus 1 then collectively performs a magnetic resonance simulation for the isochromats classified as a same group among the multiple isochromats, to output a simulation result obtained from the MR simulation. In the MR simulation apparatus 1 of the first embodiment, the physical values include a longitudinal relaxation time, a transverse relaxation time, and a non-uniform external magnetic field, the preset condition contains non-application of a gradient field in at least one direction, and the group information is based on the physical values and gradient-field applied positions of the multiple isochromats. Further, in the MR simulation apparatus 1 of the first embodiment, the preset condition contains non-application of a gradient field in two mutually orthogonal directions.

In addition, the MR simulation apparatus 1 of the first embodiment classifies the multiple isochromats into two or more groups based on the group information in the RF-pulse application period of the pulse sequence, to compute, for each of the two or more groups, transition matrices describing magnetization state transitions of the isochromats for the number of samples of the RF pulse. The MR simulation apparatus 1 then computes a magnetization state transition of each of the multiple isochromats by individually applying the group-basis transition matrices to the isochromats groups, to compute a total sum of magnetizations of the isochromats on a group basis in the MR-signal acquisition period of the pulse sequence. The MR simulation apparatus 1 further computes relaxations of the total sum of magnetizations using the physical values at MR-signal sampling intervals and on a group basis. By summing the relaxations for the groups, the computing function 175 computes magnetic resonance signals to be acquired at sampling intervals.

As such, with respect to the periods where improved computation accelerating effects are expected, such as during no application of a gradient field and during application of a single-axis gradient field, the MR simulation apparatus 1 of the first embodiment can create tables that allow avoidance of redundant computations at the positions of the same field strength in units of phantoms, and can perform computations in the RF-pulse application and in the MR-signal acquisition (ADC) without performing redundant computations, by selecting a suitable table for the pulse sequence used in the MR simulation concerned. In addition, in the MR simulation apparatus 1 of the first embodiment, the phantom updating frequency is likely to be considerably lower than the pulse-sequence updating frequency, which allows reuse of the phantom-basis table for the same phantom in accordance with the pulse sequence.

Consequently, the MR simulation apparatus 1 of the first embodiment can perform computations in units of groups for each of the phantoms in the RF application period and the acquisition period, thereby decreasing the computation amounts of MR simulations, that is, reducing the computational costs related to the Broch simulations. In this manner, the MR simulation apparatus 1 of the first embodiment can accelerate the computations of the MR simulation.

### First Application

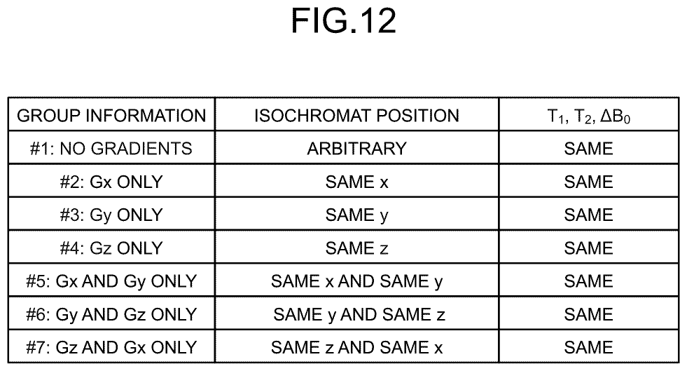

According to the first embodiment, the group information represents isochromat groups, with two-axial gradient fields set to zero out of three-axial gradient fields. A first application involves grouping isochromats, with single-axial and two-axial gradient fields set to zero out of three-axial gradient fields. In this case the group information of FIG. 4 is generated on a phantom basis as shown in FIG. 12.

FIG. 12 illustrates an example of the group information according to the first application. As illustrated in FIG. 12, the group information includes group information #5 and #6 in addition to the group information #1 to #4 of FIG. 4. Under a predetermined condition that gradient fields Gx and Gy only are applied, the same fifth index is assigned to the same-property isochromats with the same physical value at the same x and y positions among the multiple isochromats, referring to the look-up table #5. In other words, different fifth indexes are assigned to isochromats having different physical values at different x and y coordinates.

Under a predetermined condition that gradient fields Gy and Gz only are applied, the same sixth index is assigned to the same-property isochromats with the same physical value at the same y and z positions among the multiple isochromats, referring to the look-up table #6. In other words, different sixth indexes are assigned to isochromats having different physical values at different y and z coordinates. Under a predetermined condition that gradient fields Gz and Gx only are applied, the same sixth index is assigned to the same-property isochromats with the same physical value at the same z and x positions among the multiple isochromats, referring to the look-up table #7. In other words, different seventh indexes are assigned to isochromats having different physical values at different z and x coordinates. The look-up table shown in FIG. 12 is generated on a phantom basis for storage in the memory 15.

The steps of the MR simulation process in the first application are similar to those in FIG. 5, therefore, a description thereof is omitted. The MR simulation apparatus 1 of the first application can perform computations in units of groups without performing redundant computations as long as the pulse sequence includes a portion corresponding to any of the group information #5 to #7 in FIG. 12. By such computations, the MR simulation apparatus 1 of the first application can further reduce the computation amounts of the MR simulations. The rest of the effects are similar to or the same as those of the first embodiment, so that a description thereof is omitted.

### Second Application

A second application involves computing the ADC values with the reception-coil sensitivity taken into account. According to the second application, for example, the processing circuitry 17 uses the computing function 175 to compute the group magnetization M_{(g)xy}(t), taking the reception-coil sensitivity according to the isochromat position into account, i.e., by weighted addition. The subsequent computation processes are the same as those in the first embodiment, therefore, a description thereof is omitted.

The addition of the reception-coil sensitivity is not limited to the above-described method. For example, the computing function 175 may precompute group-related sensitivity according to the isochromat positions to compute the sum of the right side of Expression (3) by a sum of product of the group-related sensitivity and the group magnetization M_{(g)xy}(t), i.e., weighted addition of the group magnetization M_{(g)xy}(t) by the sensitivity. Known addition methods of the reception-coil sensitivity are available, therefore, a description thereof is omitted.

### Third Application

A third application includes applying clustering to a map representing a distribution of physical values generated from a phantom (hereinafter, referred to as a physical-value map), to thereby generate a physical-value map with smoothened variations (data) in physical value (hereinafter, referred to as a smooth map). The third application further includes performing the MR simulation process using the smooth map to generate nuclear magnetization M₀ maps in the direction of the static magnetic field with improved image quality. The nuclear magnetization M₀ in the direction of the static magnetic field refers to a nuclear magnetization in an equilibrium state under the static magnetic field (hereinafter, referred to as equilibrium magnetization).

The input interface 11 receives a user instruction as to whether to perform clustering. Prior to the MR simulation process, for example, the display included in the output interface 13 displays a user interface that allows the user to designate execution or non-execution of the clustering and the number of clusters in the clustering process. The user gives an instruction for executing or not executing clustering via the input interface 11. The user may input the number of clusters for execution of the clustering through the input interface 11. The designation of the number of clusters is not limited to an input of a value corresponding to the number of clusters, and may be, for example, a selection of the number of clusters from among 16 to 128. As such, the input interface 11 receives an instruction as to execution or non-execution of the clustering of the physical-value map based on the phantom and an input of the number of clusters in the clustering process.

The processing circuitry 17 uses the computing function 175 to perform clustering of the physical-value map into the designated number of clusters, prior to performing the magnetic resonance simulation. Any known clustering method may be applicable, including, for example, the k-means method and the Mean Shift method. In such a manner the computing function 175 can generate smooth property maps. The smooth property maps are, for example, obtained by clustering the physical-value map into 16 to 128 clusters and correspond to physical-value maps with variations (data) in physical value smoothened. Various kinds of computer programs for the clustering process are pre-stored in the memory 15. The computing function 175 stores the smooth property maps in the memory 15.

The processing circuitry 17 uses the computing function 175 to perform a magnetic resonance simulation using the clustered physical-value maps (smooth maps). In the magnetic resonance simulation, the smooth maps are, for example, used for generation and selection of the group information in FIG. 4. The computing function 175 computes a nuclear magnetization map M₀ in the direction of the static magnetic field as a simulation result. The output function 177 outputs the nuclear magnetization map M₀ in the direction of the static magnetic field as a simulation result.

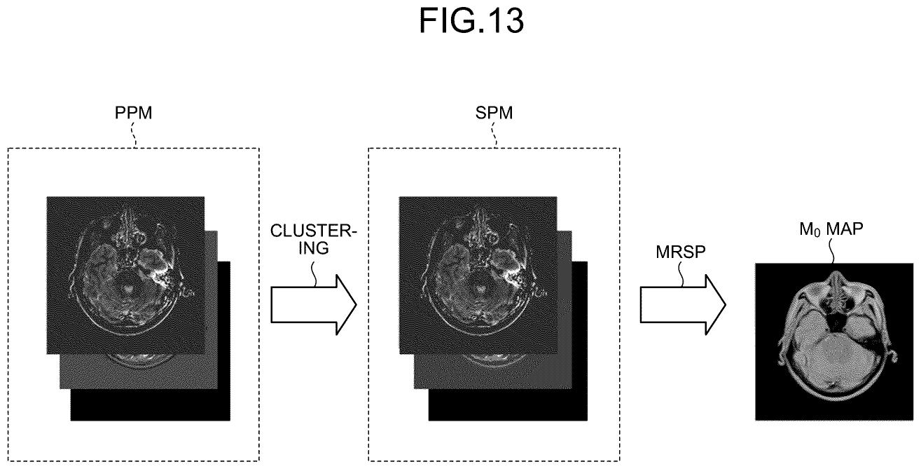

FIG. 13 illustrates an outline of an M₀ map generation process including the clustering, as an example. As illustrated in FIG. 13, prior to an MR simulation process MRSP, physical-value maps PPM based on a phantom are subjected to clustering to generate smooth maps SPM. The M₀ map is generated from the smooth maps SPM through the MR simulation process MRSP.

The MR simulation apparatus 1 of the third application receives an instruction as to execution or non-execution of clustering of the phantom-basis physical-value maps and an input of the number of clusters for use in the clustering. Before performing a magnetic resonance simulation, the MR simulation apparatus 1 subjects the physical-value maps to clustering to group them into the number of clusters and then performs a magnetic resonance simulation using the clustered physical-value maps. As such, the MR simulation apparatus 1 of the third application can generate the nuclear magnetization maps M₀ in the direction of the static magnetic field with higher precision and accuracy. The rest of the effects are similar to or the same as those of the first embodiment, so that a description thereof is omitted.

### Second Embodiment

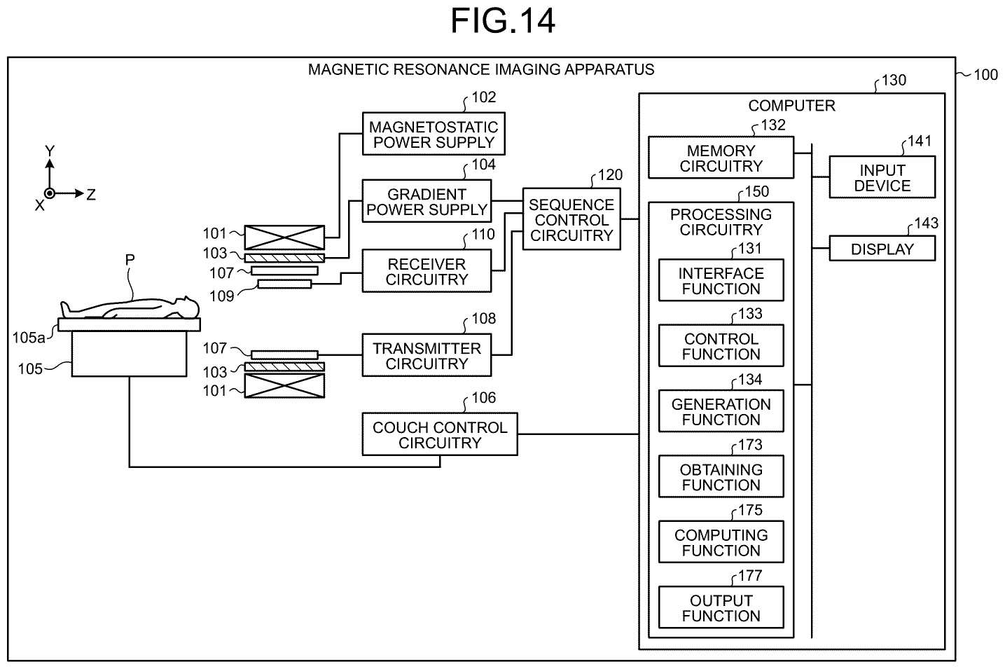

A second embodiment uses an MRI apparatus to implement the MR simulation process performed by the respective functions of the MR simulation apparatus 1 described in the first embodiment. The MRI apparatus of the second embodiment includes various kinds of elements for performing the MR simulation process. FIG. 14 illustrates an exemplary configuration of an MRI apparatus 100 according to the second embodiment.

As illustrated in FIG. 14, the MRI apparatus 100 includes magnetostatic magnets 101, a magnetostatic power supply 102, gradient coils 103, a gradient power supply 104, a couch 105, couch control circuitry 106, transmission coils 107, transmitter circuitry 108, a reception coil 109, receiver circuitry 110, sequence control circuitry 120, and a computer (also referred to as image processing apparatus or information processing apparatus) 130. The MRI apparatus 100 does not include a subject P (such as a human body). The structure and configuration illustrated in FIG. 1 are merely exemplary. As an example, the elements inside both the sequence control circuitry 120 and the computer 130 may be integrated or separated when appropriate. The computer 130 can be incorporated in a console, for example.

The magnetostatic magnets 101 are hollow, substantially cylindrical magnets to generate static magnetic fields in the internal space. Examples of the magnetostatic magnets 101 include a superconducting magnet that magnetizes, supplied with a current from the magnetostatic power supply 102. The magnetostatic power supply 102 supplies currents to the magnetostatic magnets 101. The magnetostatic magnets 101 can be permanent magnets. In this case the MRI apparatus 100 may not include the magnetostatic power supply 102 or the magnetostatic power supply 102 may be separated from the MRI apparatus 100.

The gradient coils 103 are hollow, substantially cylindrical coils and located inside the magnetostatic magnets 101. Each gradient coil 103 is a combination of three coils corresponding to mutually orthogonal X-axis, Y-axis, and Z-axis. The three coils are individually supplied with currents from the gradient power supply 104, to generate gradient fields that vary in field strength along the X, Y, and Z-axes. The gradient fields generated along the X, Y, and Z-axes by the gradient coils 103 are exemplified by a slice gradient field Gs, a phase-encoding gradient field Ge, and a readout gradient field Gr. The gradient power supply 104 supplies currents to the gradient coils 103.

The couch 105 includes a couch top 105a on which the subject P is to be laid. Under the control of the couch control circuitry 106, the couch top 105a with the subject P lying thereon is inserted into a hollow (imaging region) between the gradient coils 103. The couch 105 is typically installed such that its longitudinal side is parallel to the axes of the magnetostatic magnets 101. The couch control circuitry 106 drives the couch 105 to move the couch top 105a longitudinally and vertically under the control of the computer 130.

The transmission coils 107 are located inside the gradient coils 103, to generate high-frequency magnetic fields, supplied with an RF pulse from the transmitter circuitry 108. The transmitter circuitry 108 supplies RF pulses corresponding to the Larmor frequency to the transmission coils 107. The Larmor frequency is defined by a type of target atoms and a magnetic field strength.

The reception coil 109 is located inside the gradient coils 103, to receive MR signals when issued from the subject P due to an influence of the high-frequency magnetic field. The reception coil 109 outputs the MR signals to the receiver circuitry 110 upon receipt.

The transmission coils 107 and the reception coil 109 as described above are merely exemplary. Each of the transmission coils 107 and the reception coil 109 may be one or a combination of a coil having a transmission function alone, a coil having a reception function alone, and a coil having both transmission and reception functions.

The receiver circuitry 110 detects the MR signals output from the reception coil 109 and generates MR data from the detected MR signals. Specifically, the receiver circuitry 110 generates MR data by converting the MR signals output from the reception coil 109 into digital signals. The receiver circuitry 110 transmits the MR data to the sequence control circuitry 120. The receiver circuitry 110 may be included in a gantry apparatus equipped with the magnetostatic magnets 101 and the gradient coils 103.

The sequence control circuitry 120 performs imaging of the subject P by driving the gradient power supply 104, the transmitter circuitry 108, and the receiver circuitry 110 based on sequence information transmitted from the computer 130. Herein, the sequence information is defined as a pulse sequence related to the subject P for the sake of specificity. The pulse sequence is generated in advance or generated in response to a user instruction given via an input device 141, and stored in memory circuitry 132.

For example, the sequence control circuitry 120 performs a pulse sequence to acquire MR data of the subject P. The sequence control circuitry 120 stores the MR data in the memory circuitry 132.

The sequence control circuitry 120 receives the MR data from the receiver circuitry 110 as a result of driving the gradient power supply 104, the transmitter circuitry 108, and the receiver circuitry 110 to image the subject P. The sequence control circuitry 120 transfers the MR data to the computer 130. Examples of the sequence control circuitry 120 include integrated circuitry such as an application specific integrated circuit (ASIC) and a field programmable gate array (FPGA), and electronic circuitry such as a CPU and an MPU. The sequence control circuitry 120 corresponds to a sequence control unit.

The computer 130 performs control of the MRI apparatus 100 as a whole and generates images, for example. The computer 130 includes the memory circuitry 132, the input device 141, a display 143, and processing circuitry 150. The processing circuitry 150 includes an interface function 131, a control function 133, a generation function 134, an obtaining function 173, a computing function 175, and an output function 177.

Processing and functions to be performed by the interface function 131, the control function 133, the generation function 134, the obtaining function 173, the computing function 175, and the output function 177 are stored in the memory circuitry 132 in program format executable by the computer 130. The processing circuitry 150 is a processor that retrieves and executes the computer programs from the memory circuitry 132 to implement the functions corresponding to the respective computer programs. In other words, having retrieved the computer programs, the processing circuitry 150 includes the respective functions shown inside the processing circuitry 150 of FIG. 4.

FIG. 14 depicts an example that the single piece of processing circuitry 150 implements the processing and functions of the interface function 131, the control function 133, the generation function 134, the obtaining function 173, computing function 175, and the output function 177. Alternatively, the processing circuitry 150 may be constituted of a combination of independent processors so that the processors can individually implement the functions by executing the computer programs. In other words, the above functions may be configured as individual computer programs to be executed by the single piece of processing circuitry 150, or particular function or functions may be incorporated in dedicated, independent program-executable circuitry.

The term “processor” used herein signifies, for example, circuitry such as a CPU, a GPU, an application specific integrated circuit, or a programmable logic device (e.g., a simple programmable logic device (SPLD), a complex programmable logic device (CPLD), and a field programmable gate array (FPGA)). The processor retrieves and executes the computer programs from the memory circuitry 132 to implement the functions.

In place of being stored in the memory circuitry 132, the computer programs may be directly embedded in the circuitry of the processor. In such a case the processor retrieves and executes the computer programs from the circuitry to implement the functions. Likewise, the couch control circuitry 106, the transmitter circuitry 108, the receiver circuitry 110, and the sequence control circuitry 120 each include electronic circuitry such as the above processor.

The memory circuitry 132 stores therein MR data as received by the interface function 131 of the processing circuitry 150, various kinds of data obtained by the obtaining function 173, various kinds of image data generated by the generation function 134, programs for use in computation by the computing function 175, results of the computation by the computing function 175, output programs for use by the output function 177, and output results from the output function 177, for example.

As an example, the memory circuitry 132 stores the phantom information and group information obtained by the obtaining function 173. The memory circuitry 132 stores the ADC values (ADCs(t)) computed by the computing function 175. The memory circuitry 132 stores the simulation results output from the output function 177.

The memory circuitry 132 further stores MR data arranged in a k-space (also referred to as k-space data) by the control function 133. The memory circuitry 132 can be implemented by, for example, a semiconductor memory device such as a random access memory (RAM) or a flash memory, a hard disc, or an optical disc. The memory circuitry 132 may be referred to as a memory.

The input device 141 receives various kinds of instructions and information inputs from the user. Examples of the input device 141 include a trackball, a switch button, a mouse, a keyboard, a touchpad that allows input by touch on the operation surface, a touch screen as an integration of a display screen and a touchpad, non-contact input circuitry including an optical sensor, and audio input circuitry. The input device 141 is electrically connected to the processing circuitry 150 to convert user inputs into electrical signals and outputs them to the processing circuitry 150. The input device 141 corresponds to an input unit.

In this disclosure, the input device 141 is not limited to the one including physical operational component or components (input interface) as a mouse and a keyboard. Other examples of the input device 141 include electrical-signal processing circuitry that receives an electrical signal corresponding to an input from an external input device separated from the MRI apparatus 100 to output the electrical signal to the control circuitry. The input device 141 may be referred to as an input interface or an operation device.

Under the control of the control function 133 of the processing circuitry 150, the display 143 displays a graphical user interface that allows the user to input an imaging condition and else, and displays images generated by the generation function 134 of the processing circuitry 150. Examples of the display 143 include a cathode ray tube (CRT) display, a liquid crystal display (LCD), an organic electroluminescence display (OELD), a light-emitting diode (LED) display, a plasma display, any of other displays known in related art, and a display device as a monitor. The display 143 corresponds to a display unit.

The processing circuitry 150 uses the interface function 131 to transmit the sequence information to the sequence control circuitry 120 and receive MR data from the sequence control circuitry 120. Further, the processing circuitry 150 uses the interface function 131 to store the MR data in the memory circuitry 132 upon receipt. The processing circuitry 150 implementing the interface function 131 corresponds to an interface unit.

The processing circuitry 150 uses the control function 133 to control the MRI apparatus 100 as a whole and control image generation and image display. For example, the processing circuitry 150 uses the control function 133 to receive an input of an imaging condition (imaging parameters, etc.) via the GUI and to generate sequence information according to a saturation pulse condition set by the received imaging condition. The processing circuitry 150 uses the control function 133 to transmit the generated sequence information to the sequence control circuitry 120. The processing circuitry 150 implementing the control function 133 corresponds to a control unit.

The processing circuitry 150 uses the generation function 134 to generate images by retrieving k-space data from the memory circuitry 132 and subjecting the k-space data to reconstruction processing such as Fourier transformation. For example, the generation function 134 generates MR images of the subject P based on MR data. The generation function 134 stores the resultant MR images in the memory circuitry 132. The MR images can be generated by any known method when appropriate, therefore, a description thereof is omitted. The processing circuitry 150 implementing the generation function 134 corresponds to a generator unit.

Alternatively, the generation function 134 may arrange ADC values (ADCs(t)) being a simulation result of the computing function 175 in the k-space and subjects the ADC values to reconstruction processing such as Fourier transformation to generate images (hereinafter, referred to as simulation images). The generation function 134 then stores the simulation images in the memory circuitry 132. The simulation image generation is similar to the MR image generation, therefore, a description thereof is omitted.

The processing circuitry 150 uses the obtaining function 173 to obtain a pulse sequence to be performed by the sequence control circuitry 120 from the memory circuitry 132. The obtaining function 173 further obtains phantom information and group information. The obtaining process is similar to that in the first embodiment, so that a description thereof is omitted.

The processing circuitry 150 uses the computing function 175 to collectively perform a magnetic resonance simulation for the isochromats of each group included in the group information associated with a predetermined condition when the pulse sequence to be performed by the sequence control circuitry 120 satisfies the predetermined condition. The magnetic resonance simulations performed by the computing function 175 are similar to those in the first embodiment, therefore, a description thereof is omitted.

The processing circuitry 150 uses the output function 177 to output, to the memory circuitry 132, a simulation result obtained from the computation of the magnetic resonance simulation by the computing function 175, for example. The output function 177 also outputs the simulation image generated by the generation function 134 to the display 143. The output process by the output function 177 is similar to that in the first embodiment, therefore, a description thereof is omitted.

The MRI apparatus 100 of the second embodiment as configured above performs the MR simulation process in the same manner as the MR simulation apparatus 1 of the first embodiment, so that a description thereof is omitted. In addition, the MR simulation process of the second embodiment may include arranging the ADC values (ADCs(t)) computed by the computing function 175 in the k-space to subject the ADC values to reconstruction processing such as Fourier transformation to generate simulation images. The output function 177 may then store the simulation images in the memory circuitry 132 and/or display them on the display 143.

The MRI apparatus 100 according to the second embodiment described above obtains phantom information and group information. The phantom information represents a phantom having an ensemble of positions and physical values relative to multiple isochromats, and the group information represents groups of isochromats classified with respect to the phantom information, the isochromats that exhibit the same physical magnetization property under a condition preset according to a pulse sequence. Based on the group information and the phantom information, the MRI apparatus 100 then collectively performs a magnetic resonance simulation with respect to the isochromats classified as a same group among the multiple isochromats, to output a simulation result obtained from the magnetic resonance simulation. The effects of the MRI apparatus 100 in the second embodiment are similar to or the same as those in the first embodiment, therefore, a description thereof is omitted.

To implement the technical ideas of one embodiment by a magnetic resonance simulation method, the magnetic resonance simulation method includes obtaining phantom information and group information, the phantom information representing a phantom having an ensemble of positions and physical values relative to multiple isochromats, the group information representing groups of isochromats classified with respect to the phantom information, the isochromats that exhibit the same physical magnetization property under a condition preset according to a pulse sequence; collectively performing a magnetic resonance simulation with respect to isochromats classified as a same group among the multiple isochromats, based on the group information and the phantom information; and outputting a simulation result obtained from the magnetic resonance simulation. The procedure and effects of the MR simulation process are similar to or the same as those in the first embodiment, therefore, a description thereof is omitted

According to a modification of the first embodiment, for example, a magnetic resonance simulation apparatus may include a display unit, an input unit, a computation unit, and an output unit. The display unit displays a user interface that allows a user to give an instruction as to whether to perform clustering of a map of physical values based on phantom information and/or input the number of clusters in the clustering. The phantom information represents a phantom having an ensemble of positions and physical values relative to multiple isochromats. The input unit receives an input to the user interface. The computation unit performs clustering of the map of physical values according to the input to the user interface, and performs a magnetic resonance simulation with respect to the multiple isochromats, using the map of physical values having undergone the clustering. The output unit outputs a simulation result obtained from the magnetic resonance simulation. The display unit, input unit, computation unit, and output unit of this modification, the functions performed by these units, and the procedure and effects of the MR simulation process are similar to or the same as those in the first embodiment and the second embodiment, therefore, a description thereof is omitted.

According to at least one of the embodiments and applications described above, it is possible to decrease the amounts of computation, i.e., reduce the computational costs for the magnetic resonance simulation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance simulation apparatus comprising
processing circuitry configured to:
obtain phantom information and group information, the phantom information representing a phantom having an ensemble of positions and physical values relative to a plurality of isochromats, the group information representing groups of isochromats classified with respect to the phantom information, the isochromats that exhibit a same physical magnetization property under a condition preset according to a pulse sequence;
collectively perform a magnetic resonance simulation with respect to isochromats classified as a same group among the plurality of isochromats, based on the group information and the phantom information; and
output a simulation result obtained from the magnetic resonance simulation.

2. The magnetic resonance simulation apparatus according to claim 1, wherein
the physical values include a longitudinal relaxation time, a transverse relaxation time, and a non-uniform external magnetic field,
the condition includes non-application of a gradient field in at least one direction, and
the group information is based on the physical values and an applied position of the gradient field.

3. The magnetic resonance simulation apparatus according to claim 2, wherein
the condition includes non-application of the gradient field in two mutually orthogonal directions.

4. The magnetic resonance simulation apparatus according to claim 1, wherein
the processing circuitry is configured to:
classify, based on the group information, the plurality of isochromats into two or more groups in an RF-pulse application period in the pulse sequence,
compute, for a number of samples of the RF pulse, transition matrices describing magnetization state transitions of the isochromats in each of the two or more groups,
compute a magnetization state transition of each of the plurality of isochromats by individually applying the transition matrices to the two or more groups of isochromats,
compute a total sum of magnetizations of the isochromats in each of the two or more groups in an acquisition period of magnetic resonance signals in the pulse sequence,
compute a relaxation of the total sum of magnetizations in each of the two or more groups at sampling intervals of the magnetic resonance signals by using the physical values, and
compute the magnetic resonance signals to be acquired at the sampling intervals by summing relaxations of the two or more groups.

5. The magnetic resonance simulation apparatus according to claim 1, further comprising:
an input interface that receives an instruction as to whether to perform clustering of a map of the physical values based on the phantom, and receives an input of the number of clusters in the clustering, wherein
the processing circuitry is configured to:
prior to performing the magnetic resonance simulation, perform the clustering of the map of the physical values into the number of clusters, and
perform the magnetic resonance simulation using the map of the physical values having undergone the clustering.

6. A magnetic resonance simulation method comprising:
obtaining phantom information and group information, the phantom information representing a phantom having an ensemble of positions and physical values relative to a plurality of isochromats, the group information representing groups of isochromats classified with respect to the phantom information, the isochromats that exhibit a same physical magnetization property under a condition preset according to a pulse sequence;
collectively performing a magnetic resonance simulation with respect to isochromats classified as a same group among the plurality of isochromats, based on the group information and the phantom information; and
outputting a simulation result obtained from the magnetic resonance simulation.

7. A magnetic resonance imaging apparatus comprising
processing circuitry configured to:
obtain phantom information and group information, the phantom information representing a phantom having an ensemble of positions and physical values relative to a plurality of isochromats, the group information representing groups of isochromats classified with respect to the phantom information, the isochromats that exhibit a same physical magnetization property under a condition preset according to a pulse sequence;
collectively perform a magnetic resonance simulation with respect to isochromats classified as a same group among the plurality of isochromats, based on the group information and the phantom information; and
output a simulation result obtained from the magnetic resonance simulation.

8. A magnetic resonance simulation apparatus comprising:
a display that displays a user interface that allows a user to input an instruction as to whether to perform clustering of a map of physical values based on phantom information and/or to input the number of clusters in the clustering, the phantom information representing a phantom having an ensemble of positions and the physical values relative to a plurality of isochromats;
an input interface that receives an input to the user interface; and
processing circuitry configured to:
perform clustering of the map of physical values according to the input to the user interface,
perform a magnetic resonance simulation with respect to the plurality of isochromats, using the map of physical values having undergone the clustering, and
output a simulation result obtained from the magnetic resonance simulation.
